(19) United States
(12) Patent Application Publication
(10) Pub. No.: US 2026/0334059 A1
(43) Pub. Date: Oct. 22, 2026

(54) DISPLAY PANEL AND DISPLAY DEVICE

(71) Applicant: WUHAN TIANMA MICROELECTRONICS CO, LTD., Shanghai (CN)

(72) Inventors: Zhiyong XIONG, Shanghai (CN); Chenmin DING, Shanghai (CN); Shifeng LIU, Shanghai (CN)

(21) Appl. No.: 19/691,098

(22) Filed: May 28, 2026

(30) Foreign Application Priority Data
Mar. 24, 2026 (CN) 202610369341.9

(51) Int. Cl. H10K 59/80

(52) U.S. Cl. CPC H10K 59/873; H10K 59/878

(57) ABSTRACT

A display panel and a display device. The display panel has a non-display region. The display panel includes: a first substrate, an encapsulation adhesive, a reflective portion and an electrostatic protection portion. The encapsulation adhesive is at least partially located in the non-display region and located on a side of the first substrate. The reflective portion is located between the encapsulation adhesive and the first substrate along a direction perpendicular to a plane of the first substrate, and at least partially overlaps the encapsulation adhesive. The electrostatic protection portion is located on a side of the reflective portion adjacent to an edge of the display panel along a direction parallel to the plane of the first substrate. The electrostatic protection portion includes at least two sub-portions arranged at intervals. The at least two sub-portions are connected to the reflective portion.

### CROSS-REFERENCE TO RELATED APPLICATION

The present application claims priority to Chinese Patent Application No. 202610369341.9, filed on Mar. 24, 2026, the content of which is incorporated herein by reference in its entirety.

### TECHNICAL FIELD

The present disclosure relates to the field of display technologies, and in particular, to a display panel and a display device.

### BACKGROUND

OLED (Organic Light-Emitting Diode) display panels are widely used in the field of display technology due to its advantages of active light emission, high contrast, no viewing angle limitation, and flexible display.

At present, in order to improve anti-water and anti-oxygen characteristics of various OLED devices in the flexible OLED display panel, an encapsulation adhesive is usually used to encapsulate a display panel. In addition, the display panel further requires performance such as electrostatic protection. Many such requirements lead to a large difficulty in structural design of a non-display region of the display panel.

### SUMMARY

Embodiments of the present disclosure provide a display panel and a display device, which can improve encapsulation reliability and anti-electrostatic capability of the display panel and reduce a width of a non-display region of the display panel.

In an aspect, the present disclosure provides a display panel. The display panel has a non-display region. The display panel includes: a first substrate, an encapsulation adhesive, a reflective portion and an electrostatic protection portion. The encapsulation adhesive is at least partially located in the non-display region and located on a side of the first substrate. The reflective portion is located between the encapsulation adhesive and the first substrate along a direction perpendicular to a plane of the first substrate, and at least partially overlaps the encapsulation adhesive. The electrostatic protection portion is located on a side of the reflective portion adjacent to an edge of the display panel along a direction parallel to the plane of the first substrate. The electrostatic protection portion includes at least two sub-portions arranged at at least one interval. The at least two sub-portions are connected to the reflective portion.

In another aspect, the present disclosure provides a display device. The display device includes a display panel. The display panel has a non-display region. The display panel includes: a first substrate, an encapsulation adhesive, a reflective portion and an electrostatic protection portion. The encapsulation adhesive is at least partially located in the non-display region and located on a side of the first substrate. The reflective portion is located between the encapsulation adhesive and the first substrate along a direction perpendicular to a plane of the first substrate, and at least partially overlaps the encapsulation adhesive. The electrostatic protection portion is located on a side of the reflective portion adjacent to an edge of the display panel along a direction parallel to the plane of the first substrate. The electrostatic protection portion includes at least two sub-portions arranged at at least one interval. The at least two sub-portions are connected to the reflective portion.

### BRIEF DESCRIPTION OF DRAWINGS

In order to illustrate the technical solutions in the embodiments of the present disclosure more clearly, the drawings, which are intended to be used in the description of the embodiments, are briefly described as below. Other drawings described below are merely some embodiments of the present disclosure, and other drawings may be obtained by those skilled in the art according to these drawings.

FIG. 1 is a sectional view of a display panel in a non-display region in the related art;

FIG. 2 is a sectional view of another display panel in a non-display region in the related art;

FIG. 3 is a schematic diagram of a display mother panel according to an embodiment of the present disclosure;

FIG. 4 is a schematic diagram of a display panel according to an embodiment of the present disclosure;

FIG. 5 is an enlarged schematic diagram of a non-display region of a display panel according to an embodiment of the present disclosure;

FIG. 6 is a sectional view of FIG. 5 along line BB′ according to an embodiment of the present disclosure;

FIG. 7 is a sectional view of a display panel according to another embodiment of the present disclosure;

FIG. 8 is a schematic diagram of a reflective portion and an electrostatic protection portion according to an embodiment of the present disclosure;

FIG. 9 is a schematic diagram of distribution of an electrostatic protection portion and a reflective portion in a display panel according to an embodiment of the present disclosure;

FIG. 10 is a schematic diagram of a reflective portion and an electrostatic protection portion according to another embodiment of the present disclosure;

FIG. 11 is a schematic diagram of a reflective portion and an electrostatic protection portion according to another embodiment of the present disclosure;

FIG. 12 is a schematic diagram of a reflective portion and an electrostatic protection portion according to another embodiment of the present disclosure;

FIG. 13 is a schematic diagram of a reflective portion and an electrostatic protection portion according to another embodiment of the present disclosure;

FIG. 14 is a schematic diagram of a reflective portion and an electrostatic protection portion according to another embodiment of the present disclosure;

FIG. 15 is a schematic diagram of a reflective portion and an electrostatic protection portion according to another embodiment of the present disclosure;

FIG. 16 is a sectional view of FIG. 5 along line CC′ according to an embodiment of the present disclosure;

FIG. 17 is a sectional view of FIG. 5 along line CC′ according to an embodiment of the present disclosure; and

FIG. 18 is a schematic diagram of a display device according to an embodiment of the present disclosure.

### DESCRIPTION OF EMBODIMENTS

In order to better understand technical solutions of the present disclosure, embodiments of the present disclosure are described in detail below in conjunction with the drawings.

It should be clear that the described embodiments are merely part of the embodiments of the present disclosure rather than all of the embodiments. All other embodiments obtained by those skilled in the art according to the embodiments of the present disclosure should fall within the protection scope of the present disclosure.

Terms used in the embodiments of the present disclosure are merely for the purpose of describing specific embodiments, but not intended to limit the present disclosure. The singular forms of “a/an”, “said” and “the” used in the embodiments of the present disclosure and the attached claims are also intended to include plural forms thereof, unless noted otherwise.

It should be understood that the term “and/or” used in the context of the present disclosure is to describe a correlation relation of related objects, indicating that there can be three relations, e.g., A and/or B can indicate only A, both A and B, and only B. In addition, the symbol “/” in the context generally indicates that the relation between the objects in front and at the back of “/” is an “or” relationship.

As described in the background section, current design of a non-display area of a display panel needs to consider multiple factors and is relatively difficult. In a process of implementing the embodiments of the present disclosure, the inventors have found that the display panel has multiple requirements such as improved encapsulation reliability, improved anti-drop capability, better anti-electrostatic effect and narrow borders. Therefore, a structure configuration in the non-display region has certain difficulty, and multiple effects cannot be balanced.

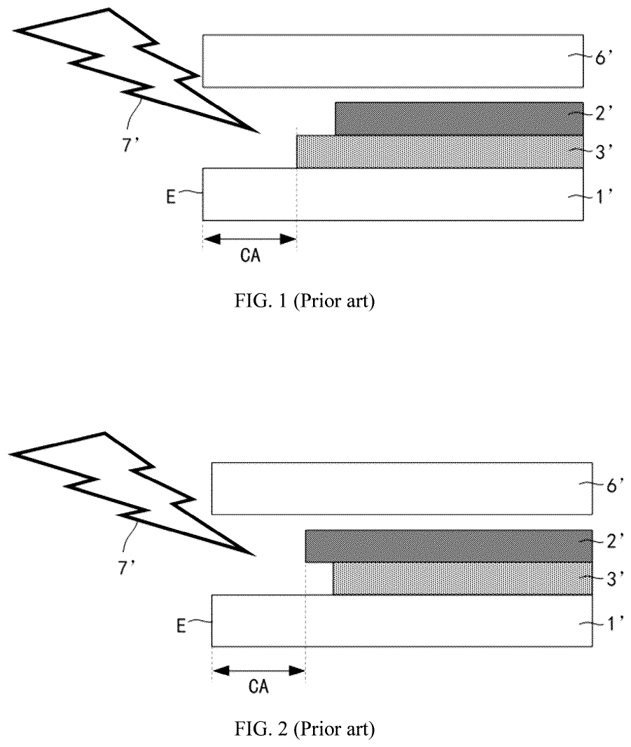

FIG. 1 is a sectional view of a display panel in a non-display region in the related art. As shown in FIG. 1, the display panel includes a first substrate 1′, an encapsulation adhesive 2′, a reflective portion 3′ and a second substrate 6′. The encapsulation adhesive 2′ is configured to bond the first substrate 1′ and the second substrate 2′, and the reflective portion 3′ is configured to improve the melting efficiency of the encapsulation adhesive 2′ during an encapsulation process. In the display panel, after the electrostatic electricity 7′ enters the display panel, a portion of the reflective portion 3′ exceeding the encapsulation adhesive 2′ may guide the electrostatic electricity, that is, the exceeding portion may be reused as an electrostatic protection portion. However, in this case, in order to ensure that the reflective portion 3′ has a portion exceeding the encapsulation adhesive 2′, a width of the encapsulation adhesive 2′ needs to be reduced. After reducing the width of the encapsulation adhesive 2′, the anti-drop capability of the display panel can be reduced. The anti-drop capability refers to a capability of not damaging the display panel after falling or dropping from a high position. In particular, under a design trend of the narrow-border display panel, the problem of poor anti-drop capability of the display panel caused by the shortened encapsulation adhesive 2′ will be more prominent.

FIG. 2 is a sectional view of another display panel in a non-display region in the related art. As shown in FIG. 2, in the non-display region, the encapsulation adhesive 2′ exceeds the reflective portion 3′ in the display panel. Based on this design, when the electrostatic verification is performed on the display panel, the encapsulation adhesive 2′ will receive the electrostatic conduction 7′ before the reflective portion 3′, and even in some cases, the electrostatic electricity 7′ will be directly strike the encapsulation adhesive 2′, resulting in burning of the encapsulation adhesive 2′, and even causing the encapsulation adhesive 2′ to fall off from the display panel, resulting in display failure of the display panel.

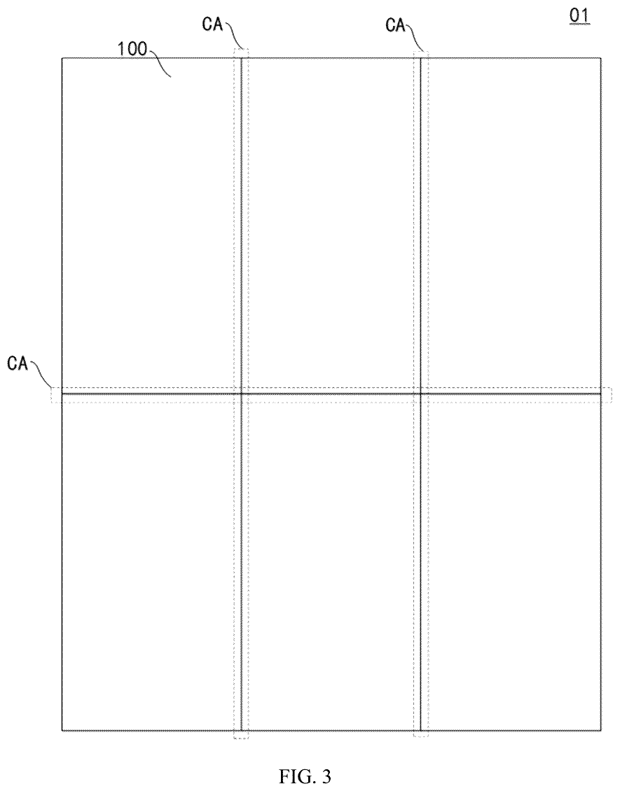

In addition, in the manufacturing process of the display panel, a display mother panel with a larger area is usually manufactured first. After manufacturing each film layer in the display mother panel, the display mother panel is cut to obtain a display panel with a smaller area. FIG. 3 is a schematic diagram of a display mother panel according to an embodiment of the present disclosure. As shown in FIG. 3, it illustrates six display panels 100 in the display mother panel 01. The display mother panel 01 includes a cutting region CA. When the display mother panel 01 is cut, a cutting line is located in the cutting region CA. In order to ensure the cutting accuracy, an edge region of the display panel formed after cutting usually retains a preset cutting region CA. As shown in FIG. 1 and FIG. 2, the cutting region CA is located on a side of the non-display region NA adjacent to an edge E of the display panel. The configuration of the cutting region CA also causes that a width of the non-display region NA of the display panel cannot be excessively compressed, which limits the realization of the narrow border of the display panel.

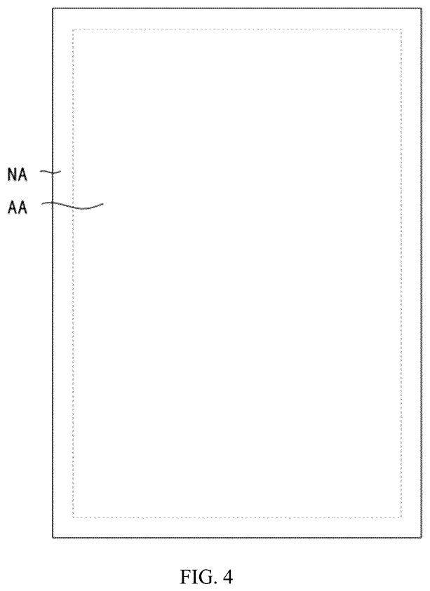

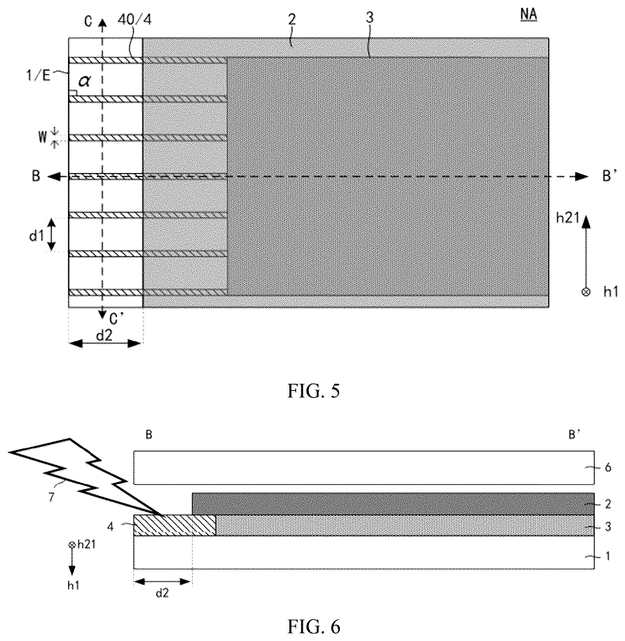

In view of this, the present disclosure provides a display panel. FIG. 4 is a schematic diagram of a display panel according to an embodiment of the present disclosure. As shown in FIG. 4, the display panel includes a non-display region NA. FIG. 5 is an enlarged schematic diagram of a non-display region of a display panel according to an embodiment of the present disclosure, and FIG. 6 is a sectional view of FIG. 5 along line BB′ according to an embodiment of the present disclosure. Referring to FIG. 4, FIG. 5 and FIG. 6, the display panel further includes a first substrate 1, an encapsulation adhesive 2, a reflective portion 3 and an electrostatic protection portion 4.

The encapsulation adhesive 2 is at least partially located in the non-display region NA, and the encapsulation adhesive 2 is located on a side of the first substrate 1. The encapsulation adhesive 2 is configured to encapsulate the display panel to avoid invasion of water and oxygen in an external environment into an interior of the display panel, thereby improving encapsulation reliability of the display panel.

Exemplarily, as shown in FIG. 1, the display panel further includes a display region AA. The display region AA includes a plurality of sub-pixels (not shown in FIG. 1). The encapsulation adhesive 2 may be configured to protect the sub-pixels from erosion by water and oxygen in the external environment, thereby improving the reliability of the display panel and prolonging the service life of the display panel.

As shown in FIG. 3, along a direction h1 perpendicular to the plane of the first substrate 1, the reflective portion 3 is located between the encapsulation adhesive 2 and the first substrate 1, and the encapsulation adhesive 2 at least partially overlaps the reflective portion 3.

In an embodiment, as shown in FIG. 6, the display panel further includes a second substrate 6, and the encapsulation adhesive 2 is located between the first substrate 1 and the second substrate 6. When the encapsulation adhesive 2 is configured to encapsulate the display panel, a colloidal encapsulation adhesive material is usually first coated at a border position of the display panel, and then the colloidal encapsulation adhesive is melted at a high temperature by laser irradiation to bond the first substrate 1 and the second substrate 6. The reflective portion 3 may reflect the incident laser to the encapsulation adhesive 2, thereby accelerating a melting rate of the encapsulation adhesive 2 and improving the utilization rate of the laser.

Exemplarily, as shown in FIG. 5 and FIG. 6, the display panel further includes an electrostatic protection portion 4. Along a direction parallel to the plane of the first substrate 1, the electrostatic protection portion 4 is located on a side of the reflective portion 3 adjacent to the edge E of the display panel. The electrostatic protection portion 4 can conduct away the electrostatic electricity entering the display panel from the edge of the display panel, thereby improving the electrostatic reliability of the display panel. For example, when the electrostatic test is performed on the display panel, the electrostatic protection portion 4 may receive the electrostatic 7 entering from the edge E of the display panel, and conduct away the electrostatic 7 in time, so as to avoid the electrostatic 7 from accumulating inside the display panel, thereby improving the electrostatic protection performance of the display panel.

In an embodiment of the present disclosure, as shown in FIG. 2, the electrostatic protection portion 4 includes at least two sub-portions 40 arranged at intervals. The sub-portions 40 are connected to the reflective portion 3. When the electrostatic test is performed on the display panel, the plurality of sub-portions 40 may jointly receive and transmit the electrostatic electricity, and the sub-portions 40 may conduct the electrostatic electricity out of the display panel through the reflective portion 3, to avoid accumulation of the electrostatic electricity inside the display panel. In an embodiment, the reflective portion 3 may be grounded.

Exemplarily, as shown in FIG. 2, the electrostatic protection portion 4 further includes a hollowed-out portion 41 located between two adjacent sub-portions 40 arranged at intervals.

In the display panel according to an embodiment of the present disclosure, the electrostatic protection portion 4 is arranged in the display panel, and the electrostatic protection portion 4 is configured to include at least two sub-portions 40, electrostatic electricity entering the interior of the display panel from the edge E of the display panel can be timely conducted away, which avoids a problem that electrostatic electricity accumulates inside the display panel to burn other structures, such as the encapsulation adhesive 2, and can improve electrostatic reliability of the display panel.

Additionally, in an embodiment of the present disclosure, by arranging two adjacent sub-portions 40 at intervals, when cutting a display mother panel, a cutting line can pass through a plurality of sub-portions 40 and a hollowed-out portion 41 located between the plurality of sub-portions 40, where the plurality of sub-portions 40 are arranged at intervals. The configuration of the hollowed-out portion 41 avoids configuring the electrostatic protection portion 4 as a whole structure with a relatively larger area, which can reduce the difficulty of cutting the display mother panel including the electrostatic protection portion 4 by a cutting tool such as a cutter wheel, thereby reusing a region of the sub-portion 40 as a cutting region for cutting the display mother panel, without the need to separately provide a cutting region for cutting in the non-display region NA. That is, with such a configuration according to the embodiment of the present disclosure, the space utilization of the non-display region can be improved, the width of the non-display region NA can be reduced, and the narrow-border design of the display panel is realized.

In addition, with such a configuration according to an embodiment of the present disclosure, the electrostatic protection portion 4 can be configured to transmit electrostatic electricity without shortening the width of the encapsulation adhesive 2, which can ensure the area of the encapsulation adhesive 2, thereby improving the anti-drop capability of the display panel. Additionally, with such a configuration, there is also no need to excessively increase the width of the encapsulation adhesive 2. For example, the encapsulation adhesive 2 and the edge E of the display panel may have a certain distance to avoid striking the electrostatic electricity 7 directly on the encapsulation adhesive 2 and avoid the encapsulation adhesive 2 from being burned by electrostatic electricity, which is beneficial to ensuring the encapsulation reliability and the display effect of the display panel.

Exemplarily, as shown in FIG. 5 and FIG. 6, along the direction h1 perpendicular to the plane of the first substrate 1, the encapsulation adhesive 2 at least partially overlaps the electrostatic protection portion 4. With such a configuration, the area of the encapsulation adhesive 2 can be increased, which is beneficial to improving the anti-drop capability of the display panel.

It should be noted that, in FIG. 5, in order to distinguish the reflective portion 3 and the encapsulation adhesive 2 more clearly, upper and lower boundaries of the two are staggered. In an actual structure of the display panel, the boundaries of the reflective portion 3 and the encapsulation adhesive 2 may overlap with each other.

In an embodiment, as shown in FIG. 5 and FIG. 6, a shortest distance between the encapsulation adhesive 2 and the edge E of the display panel adjacent thereto is d2, where d2≥300 μm. With such a configuration, the distance between the encapsulation adhesive 2 and the edge E of the display panel adjacent thereto can be increased. When the electrostatic test is performed on the display panel, the strike of electrostatic electricity directly on the encapsulation adhesive 2 is avoided, the possibility of the encapsulation adhesive 2 being injured by the electrostatic electricity is reduced, and the encapsulation reliability of the display panel is improved.

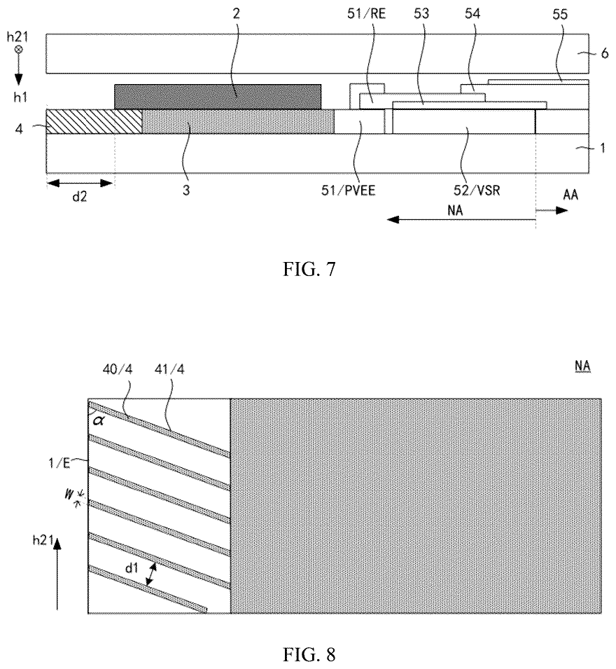

FIG. 7 is a sectional view of a display panel according to another embodiment of the present disclosure. As shown in FIG. 7, the non-display region NA further includes a driving signal line 51 and a peripheral circuit 52. Exemplarily, the driving signal line 51 includes a first power signal line PVEE and a connection trace RE, and the connection trace RE is electrically connected to the first power signal line PVEE. Exemplarily, the connection trace RE may be provided in a same layer as an anode (not shown in FIG. 7) of the light-emitting element in the display region AA.

In an embodiment, the peripheral circuit 52 includes a shift register circuit VSR, and the shift register circuit VSR may provide a control signal to sub-pixels in the display region AA.

As shown in FIG. 7, the display panel further includes a planarization layer 53, a pixel definition layer 54 and an electrode layer 55. The electrode layer 55 is located on a side of the pixel definition layer 54 away from the first substrate 1. Exemplarily, the electrode layer 55 may serve as a cathode of the light-emitting element in the display region AA.

Exemplarily, in an embodiment of the present disclosure, the extension direction of the sub-portion 40 intersects with the extension direction of the edge E of the display panel adjacent to the sub-portion 40.

As shown in FIG. 3, when the display mother panel 01 is cut, a movement trajectory of a cutting tool is parallel to an edge of the display panel 100 formed by cutting. In this embodiment of the present disclosure, the sub-portion 40 is configured to intersect with the edge E, and when the region of the sub-portion 40 is reused for cutting, the movement trajectory of the cutting tool, that is, the cutting line is exactly along the extension direction of the sub-portion 40, can be avoided, thereby reducing the contact region between the cutting tool and the sub-portion 40. Since the sub-portion 40 is usually made of metal, if the cutting tool directly contacts a large area of metal, the cutting difficulty is relatively high. In this embodiment of the present disclosure, the extension direction of the sub-portion 40 intersects with the extension direction of the edge E of the display panel adjacent to the sub-portion 40, which is equivalent to intersecting the extension direction of the sub-portion 40 with the extension direction of the cutting line, which can reduce the cutting difficulty of the display mother panel 01 and is beneficial to improving the process yield.

In an embodiment of the present disclosure, an included angle formed between the extension direction of the sub-portion 40 and the extension direction of the edge E of the display panel adjacent to the sub-portion 40 is α. For example, as shown in FIG. 5, in this embodiment of the present disclosure, α=90°. That is, the extension direction of the sub-portion 40 is perpendicular to the extension direction of the edge E of the display panel adjacent to the sub-portion 40.

FIG. 8 is a schematic diagram of a reflective portion and an electrostatic protection portion according to an embodiment of the present disclosure. As shown in FIG. 8, α can be configured as an acute angle.

When α is an acute angle, for example, in this embodiment of the present disclosure, α>45°. Based on this configuration, in the process of cutting the display mother panel 01 shown in FIG. 3 to form the display panel, when the region of the sub-portion 40 is reused as the cutting region, the contact area between the cutting tool and the sub-portion 40 can be reduced, thereby reducing the cutting difficulty of the display mother panel 01.

Exemplarily, as shown in FIG. 5 and FIG. 8, the at least two sub-portions 40 are arranged along a first direction h21, and the first direction h21 is parallel to the extension direction of the edge E of the display panel adjacent to the sub-portion 40. With such a configuration, when the cutting tool is configured to cut the display mother panel, the movement trajectory of the cutting tool can pass through the alternately arranged sub-portions 40 and hollowed-out portions 41, which can reduce the contact area between the cutting line and the sub-portions 40, and avoid moving the cutting line along the extension direction of the single sub-portion 40 through a complete single sub-portion 40 exactly, thereby reducing the cutting difficulty.

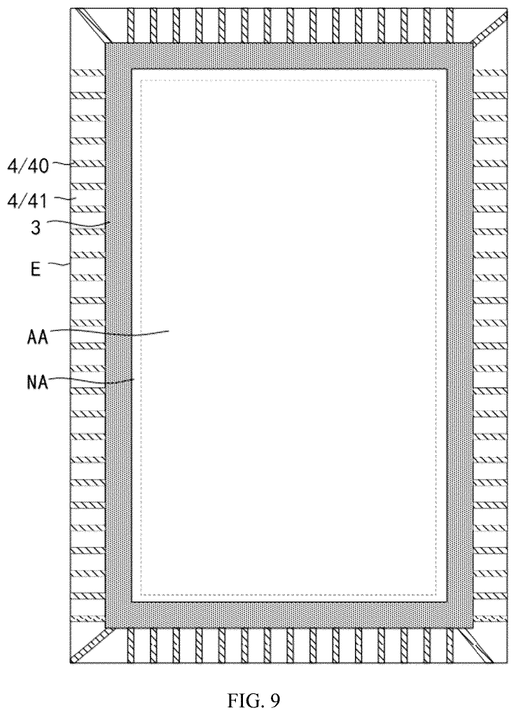

FIG. 9 is a schematic diagram of distribution of an electrostatic protection portion and a reflective portion in a display panel according to an embodiment of the present disclosure. In an embodiment, as shown in FIG. 9, the electrostatic protection portion 4 at least partially surrounds the reflective portion 3. The reflective portion 3 at least partially surrounds the display region AA. With such a configuration, the electrostatic protection portion 4 can provide protection for as many positions in the display panel as possible, which is beneficial to improving an electrostatic protection capability of the display panel.

In an embodiment, as shown in FIG. 5 and FIG. 8, a distance between two adjacent sub-portions 40 is d1, and a width of the sub-portion 40 is W, where d1>W. With such a configuration, the distance between two adjacent sub-portions 40 can be increased. When the cutting tool is configured to cut the display mother panel, the contact region between the cutting tool and the electrostatic protection portion 4 can be reduced, thereby facilitating cutting.

In an embodiment, 0.1 mm≤d1≤5 mm. With such a configuration, on the one hand, a spacing between two adjacent sub-portions 40 can be avoided from being too small, which is beneficial to reducing the manufacturing difficulty of the sub-portions 40. On the other hand, the problem that an excessively large spacing between two adjacent sub-portions 40 results in an excessively small number of sub-portions 40 at the periphery of the display region, which in turn adversely affects electrostatic conduction, can also be avoided.

Exemplarily, the manufacturing of the sub-portion 40 may adopt a process of forming a film first and then patterning. In an embodiment, the patterning process includes a photolithography process.

Exemplarily, the reflective portion 3 and the electrostatic protection portion 4 may be formed in a same process. Materials of the two may be the same to reduce the manufacturing process of the display panel. Exemplarily, materials of the two include a conductor, such as a metal.

In an embodiment of the present disclosure, the reflective portion 3 and the electrostatic protection portion 4 may also be made of different materials. In an embodiment, the reflective portion 3 and the electrostatic protection portion 4 may also be formed in different processes.

Exemplarily, the display panel further includes an array film layer, which includes structures such as traces and thin film transistors. The manufacturing of at least one of the sub-portion 40 and the reflective portion 3 may be formed in the same process as at least a part of the array film layers, so as to simplify the manufacturing process of the display panel.

In an embodiment, the width W of the sub-portion 40 may be in the order of microns. For example, W≤10 μm. When the cutting line passes through the sub-portion 40, W≤10 μm, the cutting difficulty can be reduced.

Exemplarily, the shape of the orthographic projection of the sub-portion 40 on the plane of the first substrate 1 includes a straight line, a polyline or a curve. FIG. 5, FIG. 8 and FIG. 9 illustrates that the orthographic projection of the sub-portion 40 on the plane of the first substrate 1 includes a straight line.

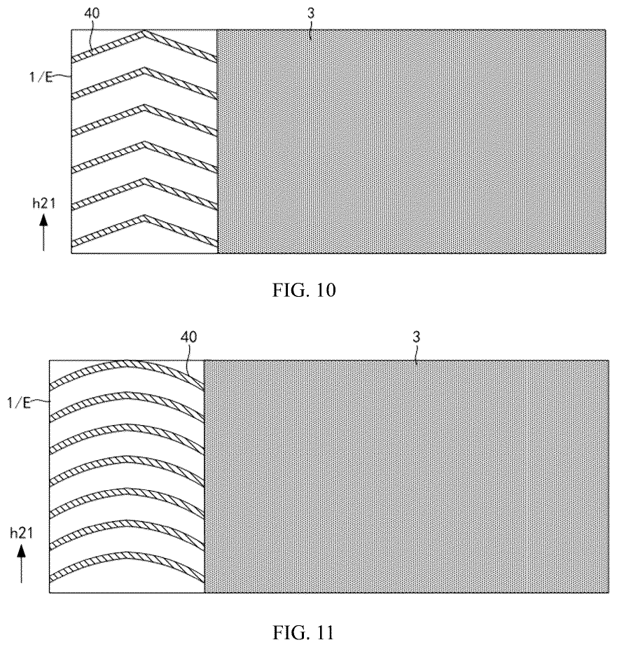

FIG. 10 is a schematic diagram of a reflective portion and an electrostatic protection portion according to another embodiment of the present disclosure. As shown in FIG. 10, a shape of an orthographic projection of the sub-portion 40 on a plane of the first substrate 1 includes a polyline.

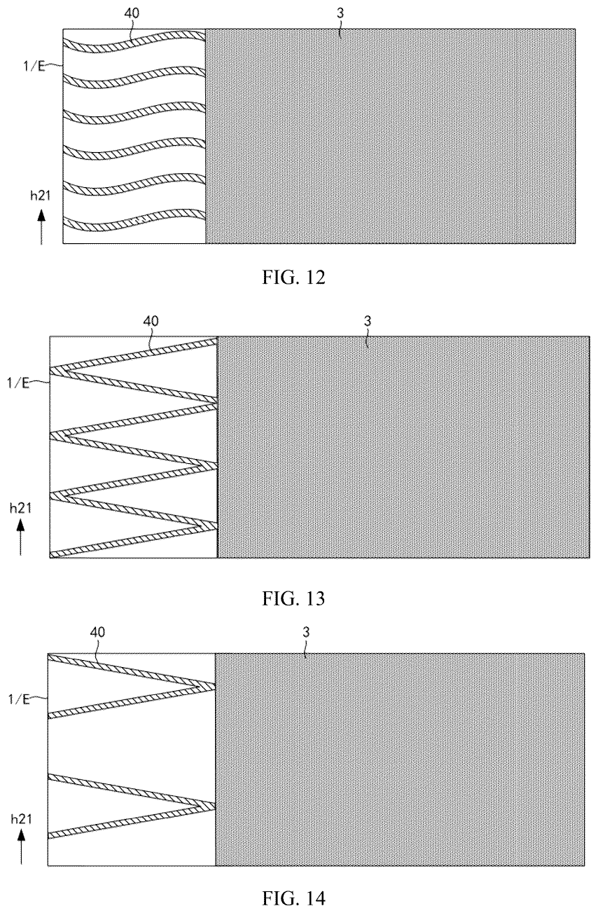

FIG. 11 is a schematic diagram of a reflective portion and an electrostatic protection portion according to another embodiment of the present disclosure, and FIG. 12 is a schematic diagram of a reflective portion and an electrostatic protection portion according to another embodiment of the present disclosure. In an embodiment, as shown in FIG. 11 and FIG. 12, a shape of the sub-portion 40 includes a curve. FIG. 11 illustrates that the curve corresponding to the sub-portion 40 has one inflection point, and FIG. 12 illustrates that the curve corresponding to the sub-portion 40 has two inflection points. It should be noted that the shape of the sub-portion 40 may also be configured to have other curved shapes, which is not limited in this embodiment of the present disclosure.

Exemplarily, as shown in FIG. 5, FIG. 8, FIG. 9, FIG. 10, FIG. 11, and FIG. 12, in this embodiment of the present disclosure, two adjacent sub-portions 40 may not be connected.

FIG. 13 is a schematic diagram of a reflective portion and an electrostatic protection portion according to another embodiment of the present disclosure, and FIG. 14 is a schematic diagram of a reflective portion and an electrostatic protection portion according to another embodiment of the present disclosure. In an embodiment, as shown in FIG. 13 and FIG. 14, at least two adjacent sub-portions 40 may be connected according to this embodiment of the present disclosure. With such a configuration, the conduction speed of the electrostatic electricity in the sub-portion 40 can be increased, and the electrostatic electricity can be conducted away from the display panel more quickly, which is beneficial to improving the electrostatic protection capability of the display panel.

In an embodiment, as shown in FIG. 13, in this embodiment of the present disclosure, a plurality of sub-portions 40 may be sequentially connected end to end. Taking an orientation shown in FIG. 13 as an example, for a sub-portion 40 located in the middle, one end thereof can be connected to a sub-portion 40 located on an upper side thereof and adjacent thereto, and the other end can be connected to a sub-portion 40 located on a lower side thereof and adjacent thereto.

Alternatively, as shown in FIG. 14, in this embodiment of the present disclosure, at least two adjacent sub-portions 40 may be taken as a group, different groups are not connected to each other, and two adjacent sub-portions 40 in a same group are electrically connected. FIG. 14 illustrates two adjacent sub-portions 40 in the same group.

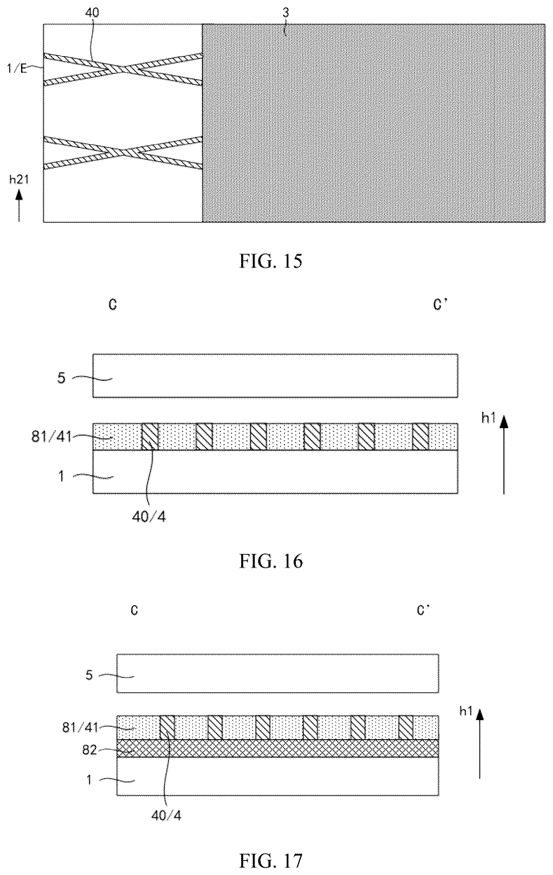

FIG. 15 is a schematic diagram of a reflective portion and an electrostatic protection portion according to another embodiment of the present disclosure. As shown in FIG. 15, two adjacent sub-portions 40 may also be electrically connected at middle portions thereof other than the end portions according to this embodiment of the present disclosure. FIG. 15 is a schematic diagram in which two adjacent sub-portions 40 are connected to form an “X” shape at the middle portions thereof.

It should be noted that when two adjacent sub-portions 40 are electrically connected, a shape of the sub-portion 40 may be any one of a straight line, a polyline, a curve, and the like, and a straight line shape of the sub-portion 40 in FIG. 13, FIG. 14, and FIG. 15 is merely illustrative.

FIG. 16 is a sectional view of FIG. 5 along line CC′ according to an embodiment of the present disclosure. Exemplarily, as shown in FIG. 16, the display panel further includes a first insulating layer 81, and the first insulating layer 81 is at least partially located between two adjacent sub-portions 40.

The configuration of the first insulating layer 81 can make an upper surface of a film layer of the sub-portion 40 flatter. In the process of cutting the display mother panel by using a cutting tool, such as a cutter wheel, and reusing the region of the sub-portion 40 as the cutting region, the flatness of the film layer contacted by the cutting tool can be improved, which is more beneficial to the cutting of the display mother panel.

In an embodiment, the first insulating layer 81 includes an inorganic insulating layer. For example, the first insulating layer 81 includes silicon nitride, silicon oxide, silicon oxynitride, or the like.

Exemplarily, when manufacturing the display panel, the sub-portions 40 arranged at intervals may be formed on the surface of the first substrate 1 first, and then the hollowed-out portion 41 between two adjacent sub-portions 40 is filled with the insulating material.

In an embodiment of the present disclosure, the thickness of the first insulating layer 81 may be equal to the thickness of the sub-portion 40, so that a surface of the first insulating layer 81 away from the substrate and a surface of the sub-portion 40 away from the substrate are coplanar. With such a configuration, when configured to cut the display mother panel, the cutting tool may fall on a plane jointly defined by the first insulating layer 81 and the sub-portion 40. A thickness direction of the first insulating layer 81 and a thickness direction of the sub-portion 40 are both perpendicular to the plane of the first substrate 1.

FIG. 17 is a sectional view of FIG. 5 along line CC′ according to an embodiment of the present disclosure. In an embodiment, as shown in FIG. 17, the display panel further includes a second insulating layer 82, and along a direction h1 perpendicular to the plane of the first substrate 1, the second insulating layer 82 is located between the electrostatic protection portion 4 and the first substrate 1. The second insulating layer 82 may increase an adhesive force between the electrostatic protection portion 4 and the first substrate 1, and increase an adhesive force between the reflective portion (not shown in FIG. 17) and the first substrate 1, thereby reducing the possibility that the electrostatic protection portion 4 and the reflective portion 3 fall off from the surface of the first substrate 1, and thus improving the encapsulation reliability and the electrostatic protection capability of the display panel.

Exemplarily, when manufacturing the display panel having the structure shown in FIG. 17, the second insulating layer 82 may be formed on the surface of the first substrate 1 first, and then the reflective portion (not shown in FIG. 17) and the sub-portion 40 are formed on the surface of the second insulating layer 82. Then, an encapsulation adhesive is formed on a side of the reflective portion away from the first substrate 1.

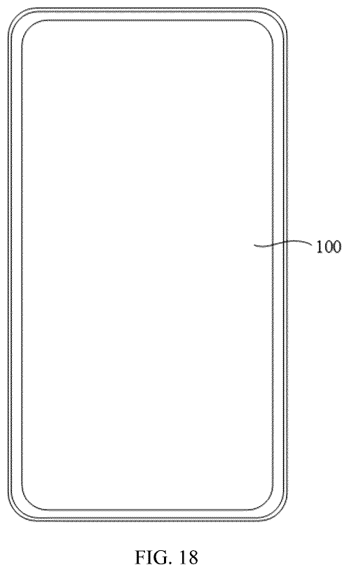

FIG. 18 is a schematic diagram of a display device according to an embodiment of the present disclosure. The present disclosure further provides a display device, as shown in FIG. 18, the display device includes the above-mentioned display panel 100. The specific structure of the display panel 100 has been described in detail in the foregoing embodiments, and details are not described herein again. It is understandable that the display device shown in FIG. 18 is merely illustrative, and the display device may be any electronic device having a display function such as a mobile phone, a tablet computer, a notebook computer, an e-book, and a television.

In the display device according to an embodiment of the present disclosure, the display panel includes the electrostatic protection portion 4, and the electrostatic protection portion 4 is configured to include at least two sub-portions 40, electrostatic electricity entering the interior of the display panel from the edge of the display panel can be timely conducted away, which avoids a problem that electrostatic electricity accumulates inside the display panel to burn other structures, such as the encapsulation adhesive 2, and can improve electrostatic reliability of the display panel.

Additionally, in an embodiment of the present disclosure, by arranging two adjacent sub-portions 40 at intervals, when cutting a display mother panel, a cutting line can pass through a plurality of sub-portions 40 and a hollowed-out portion 41 located between the plurality of sub-portions 40, where the plurality of sub-portions 40 are arranged at intervals. The configuration of the hollowed-out portion 41 avoids configuring the electrostatic protection portion 4 as a whole structure with a relatively larger area, which can reduce the difficulty of cutting the display mother panel including the electrostatic protection portion 4 by a cutting tool such as a cutter wheel, thereby reusing a region of the sub-portion 40 as a cutting region for cutting the display mother panel, without the need to separately provide a cutting region for cutting in the non-display region NA. That is, with such a configuration according to the embodiment of the present disclosure, the space utilization of the non-display region can be improved, the width of the non-display region NA can be reduced, and the narrow-border design of the display panel is realized.

In addition, with such a configuration according to an embodiment of the present disclosure, the electrostatic protection portion 4 can be configured to transmit electrostatic electricity without shortening the width of the encapsulation adhesive 2, which can ensure the area of the encapsulation adhesive 2, thereby improving the anti-drop capability of the display panel. Additionally, with such a configuration, there is also no need to excessively increase the width of the encapsulation adhesive 2. For example, the encapsulation adhesive 2 and the edge E of the display panel may have a certain distance to avoid striking the electrostatic electricity 7 directly on the encapsulation adhesive 2 and avoid the encapsulation adhesive 2 from being burned by electrostatic electricity, which is beneficial to ensuring the encapsulation reliability and the display effect of the display panel.

The above description just illustrates preferred embodiment of the present disclosure and is not intended to limit the present disclosure, and any modifications, equivalent substitutions, improvements and the like made within the spirit and principle of the present disclosure should be included within the protection scope of the present disclosure.

As above, it should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel having a non-display region and comprising:
a first substrate;
an encapsulation adhesive at least partially located in the non-display region, wherein the encapsulation adhesive is located on a side of the first substrate;
a reflective portion located between the encapsulation adhesive and the first substrate along a direction perpendicular to a plane of the first substrate, wherein the reflective portion at least partially overlaps the encapsulation adhesive; and
an electrostatic protection portion located on a side of the reflective portion adjacent to an edge of the display panel along a direction parallel to the plane of the first substrate, wherein the electrostatic protection portion comprises at least two sub-portions arranged at at least one interval, and the at least two sub-portions are connected to the reflective portion.

2. The display panel according to claim 1, wherein
an extension direction of one of the at least two sub-portions intersects with an extension direction of an edge of the display panel adjacent to the one of the at least two sub-portions.

3. The display panel according to claim 1, wherein
an acute angle formed between an extension direction of one of the at least two sub-portions and an extension direction of an edge of the display panel adjacent to the one of the at least two sub-portions is α, where α>45°.

4. The display panel according to claim 1, wherein
the at least two sub-portions are arranged along a first direction, and the first direction is parallel to an extension direction of an edge of the display panel adjacent to one of the at least two sub-portions.

5. The display panel according to claim 1, wherein
the encapsulation adhesive at least partially overlaps the electrostatic protection portion along the direction perpendicular to the plane of the first substrate.

6. The display panel according to claim 1, wherein
the electrostatic protection portion at least partially surrounds the reflective portion.

7. The display panel according to claim 1, wherein
a distance between two adjacent sub-portions is greater than a width of one of the at least two sub-portions.

8. The display panel according to claim 1, wherein
a distance between two adjacent sub-portions is d1, where 0.1 mm≤d1≤5 mm.

9. The display panel according to claim 1, wherein
a width of one of the at least two sub-portions is smaller than or equal to 10 μm.

10. The display panel according to claim 1, wherein
a shape of an orthographic projection of one of the at least two sub-portions on the plane of the first substrate comprises a straight line, a polyline, or a curve.

11. The display panel according to claim 1, wherein
at least two adjacent sub-portions of the at least two sub-portions are connected together.

12. The display panel according to claim 1, wherein
a shortest distance between the encapsulation adhesive and an edge of the display panel adjacent to the encapsulation adhesive is greater than or equal to 300 μm.

13. The display panel according to claim 1, further comprising a first insulating layer at least partially located between two adjacent sub-portions of the at least two sub-portions.

14. The display panel according to claim 1, further comprising a second insulating layer located between the reflective portion and the first substrate.

15. The display panel according to claim 1, wherein
the encapsulation adhesive comprises glass frit.

16. The display panel according to claim 1, wherein
the reflective portion and the electrostatic protection portion are formed in a same process.

17. A display device, comprising a display panel, wherein the display panel has a non-display region and comprises:
a first substrate;
an encapsulation adhesive at least partially located in the non-display region, wherein the encapsulation adhesive is located on a side of the first substrate;
a reflective portion located between the encapsulation adhesive and the first substrate along a direction perpendicular to a plane of the first substrate, wherein the reflective portion at least partially overlaps the encapsulation adhesive; and
an electrostatic protection portion located on a side of the reflective portion adjacent to an edge of the display panel along a direction parallel to the plane of the first substrate, wherein the electrostatic protection portion comprises at least two sub-portions arranged at at least one interval, and the at least two sub-portions are connected to the reflective portion.
